(19) United States
(12) Patent Application Publication
(10) Pub. No.: US 2020/0251303 A1
(43) Pub. Date: Aug. 6, 2020

(54) CHARGED PARTICLE BEAM APPARATUS

(71) Applicant: HITACHI HIGH-TECH SCIENCE CORPORATION, Minato-ku, Tokyo (JP)

(72) Inventors: Toshiaki FUJI, Minato-ku, Tokyo (JP); Satoshi TOMIMATSU, Minato-ku, Tokyo (JP); Hiroyuki SUZUKI, Minato-ku, Tokyo (JP)

(21) Appl. No.: 16/495,506

(22) PCT Filed: Mar. 27, 2018
(86) PCT No.: PCT/JP2018/012609

§ 371 Date: Sep. 19, 2019

(30) Foreign Application Priority Data
Mar. 27, 2017 (JP) 2017-060903
Mar. 22, 2018 (JP) 2018-055231

(51) Int. Cl. H01J 37/28; H01J 37/20; H01J 37/30

(52) U.S. Cl. CPC H01J 37/28; H01J 37/20; H01J 2237/20214; H01J 2237/20207; H01J 37/3005

(57) ABSTRACT

This charged particle beam apparatus is provided with: a charged particle beam lens-barrel for irradiating a sample with a charged particle beams; a tilting base that has a first sample holding portion capable of holding the sample and that holds the first sample holding portion to be turnable about a first axis; a tilting base that has a second sample holding portion capable of holding the sample and that holds the second sample holding portion to be turnable about a second axis parallel to the first axis; and a driving force supplier that supplies to the tilting bases with a driving force for turning the tilting bases in association with each other.

### RELATED APPLICATIONS

This application is a 371 application of PCT/JP2018/012609 having an international filing date of Mar. 27, 2018, with claims priority to JP2017-060903 filed Mar. 27, 2017 and JP2018-055231 filed Mar. 22, 2018, the entire content of which is incorporated herein by reference.

### TECHNICAL FIELD

The present invention relates to a charged particle beam apparatus.

### BACKGROUND ART

The charged particle beam is a generic term for the ion beam and the electron beam. An apparatus capable of performing at least one of processing, observation and analysis (hereinafter referred to observation or the like) using a focused charged particle beam is called a charged particle beam apparatus. The charged particle beam apparatus is mounted with at least one of an ion beam lens barrel forming the ion beam and an electron beam lens barrel forming the electron beam. The charged particle beam apparatus also includes a combined device on which a plurality of charged particle beam lens barrels are mounted.

Such a charged particle beam apparatus may be used, for example, to form a thin sample. When a structure such as a semiconductor device is exposed on an observation surface of the thin sample, a processing rate of the charged particle beam varies depending on the presence or absence of the structure. Thus, an unevenness is formed on the observation surface and a phenomenon of streaky appearance, so-called curtain effect occurs.

For example, Patent Literature 1 describes a composite charged particle beam apparatus capable of tilting a sample base on which a sample is placed in a biaxial direction in order to prevent the curtain effect.

### CITATION LIST

### Patent Literature

Patent Literature 1: JP-A-2014-063726

SUMMARY OF INVENTION

### Technical Problem

However, when a plurality of samples are disposed in a sample holder to process the samples in order to form a sample efficiently, the charged particle beam apparatus in the related art has the following problem.

In the composite charged particle beam apparatus described in Patent Literature 1, the sample holder is disposed such that the tilting axis passes through one sample on the sample holder. When a plurality of samples are disposed in the sample holder, the sample disposed outside the tilting axis moves about the tilting axis when the sample holder is tilted. Thus, there is a problem of repositioning each sample to a beam irradiation position. In addition, when the sample holder is tilted, there is a concern that the sample disposed outside the tilting axis collides with a structure such as a lens barrel to damage the sample.

The present invention has been made in view of the above problem, and an object of the present invention is to provide a charged particle beam apparatus capable of safely and efficiently forming a sample even in a case of processing a plurality of samples.

### Solution to Solve Problem

In order to solve the above problem, a charged particle beam apparatus according to a first aspect of the present invention includes:

a charged particle beam lens barrel that irradiates a sample with a charged particle beam;

a first tilting base that includes a first sample holding portion capable of holding the sample, and holds the first sample holding portion to be turnable about a first turning axis;

a second tilting base that includes a second sample holding portion capable of holding the sample, and holds the second sample holding portion to be turnable about a second turning axis parallel to the first turning axis; and

a driving force supplier configured to supply the first tilting base and the second tilting base with a driving force for turning the first tilting base in association with the second tilting base.

In the present description, “turn” means a revolving movement about a turning axis, limited by an angular range of less than 360°. The direction of “turn” can be two directions about the turning axis.

In the above charged particle beam apparatus, the first tilting base and the second tilting base may be disposed in a direction intersecting the first turning axis and the second turning axis.

The above charged particle beam apparatus may further include a sample stage that includes a rotation stage being rotatable about a rotation axis extending in a direction orthogonal to the first turning axis and the second turning axis, in which the first tilting base and the second tilting base may be provided on a detachable sample holder on an upper surface of the sample stage.

In the present description, “rotation” means a revolving movement about a rotation axis. That is, “rotation” means includes the meaning of both a revolving movement about the rotation axis within an angular range of less than 360° and a revolving movement about the rotation axis at an angle of 360° or more. The angle of “rotation” may or may not be limited. The direction of “rotation” may be two directions about the rotation axis or may be limited to one direction.

The above charged particle beam apparatus may further includes a tilting stage that turns the first tilting base and the second tilting base about a third turning axis orthogonal to the first turning axis and the second turning axis.

In the above charged particle beam apparatus, the first tilting base may include a first gear having the first turning axis as a pitch circle center, the second tilting base may include a second gear having the second turning axis as a pitch circle center, and the driving force supplier may include a third gear meshing with the first gear and the second gear.

In the above charged particle beam apparatus, the first gear may be a first worm wheel, the second gear may be a second worm wheel, and the third gear may be a worm meshing with the first worm wheel and the second worm wheel.

In the charged particle beam apparatus, the driving force supplier may include a drive rod that transmits the driving force to the first tilting base and the second tilting base.

### Advantageous Effects of Invention

According to the charged particle beam apparatus of the present invention, a sample can be safely and efficiently formed even in a case of processing a plurality of samples.

### BRIEF DESCRIPTION OF DRAWINGS

FIG. 1 is a schematic diagram showing an example of a configuration of a charged particle beam apparatus according to a first embodiment of the present invention.

FIG. 2 is a schematic perspective view showing a configuration of main parts of the charged particle beam apparatus according to the first embodiment of the present invention.

FIG. 3 is a schematic perspective view showing a main configuration of a sample holder in the charged particle beam apparatus according to the first embodiment of the present invention.

FIG. 4 is a detailed diagram of a portion A in FIG. 3.

FIG. 5 is a schematic front view showing an example of an internal structure of the sample holder in the charged particle beam apparatus according to the first embodiment of the present invention.

FIG. 6 is an operation illustrative diagram of the sample holder in the charged particle beam apparatus according to the first embodiment of the present invention.

FIGS. 7A and 7B show a schematic front view and side view showing the holding form of the sample in the charged particle beam apparatus according to the first embodiment of the present invention.

FIG. 8 is a schematic perspective view showing a relationship between the sample and a processing direction in the charged particle beam apparatus according to the first embodiment of the present invention.

FIG. 9 is a schematic front view showing an example of an internal structure of a sample holder in a charged particle beam apparatus according to a second embodiment of the present invention.

FIG. 10 is a schematic front view showing an example of an internal structure of a sample holder in a charged particle beam apparatus according to a third embodiment of the present invention.

FIG. 11 is a schematic front view showing an example of an internal structure of a sample holder in a charged particle beam apparatus according to a fourth embodiment of the present invention.

FIG. 12 is a schematic front view showing an example of an internal structure of a sample holder in a charged particle beam apparatus according to a modification of the fourth embodiment of the present invention.

FIG. 13 is a schematic front view showing an example of an internal structure of a sample holder in a charged particle beam apparatus according to a fifth embodiment of the present invention.

FIG. 14 is a schematic front view showing an example of an internal structure of a sample holder in a charged particle beam apparatus according to a modification of the fifth embodiment of the present invention.

### DESCRIPTION OF EMBODIMENTS

Hereinafter, embodiments of the present invention will be described with reference to the attached drawings. In all the drawings, the same or corresponding members are denoted by the same reference numerals even if the embodiment is different, and the common description is omitted.

### First Embodiment

A charged particle beam apparatus according to a first embodiment of the present invention will be described.

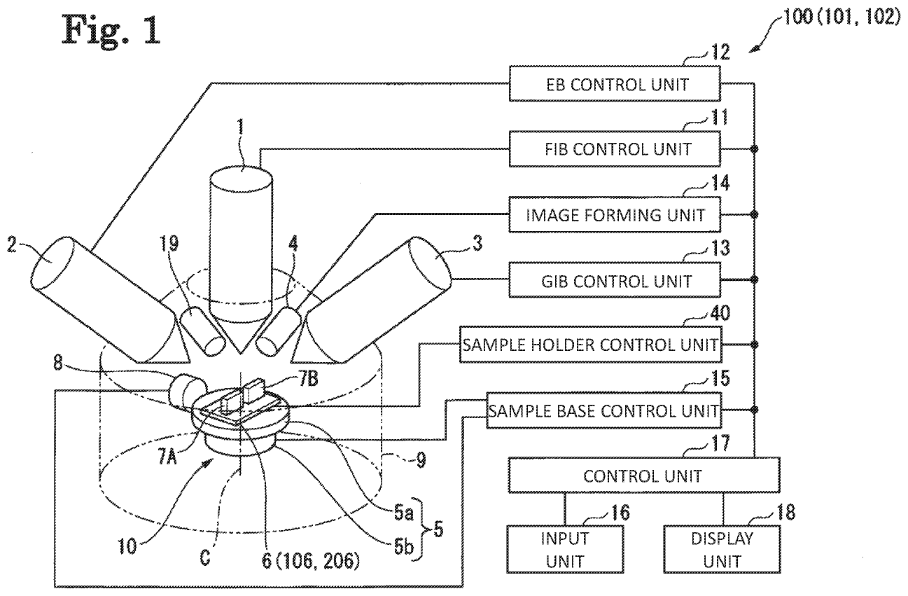

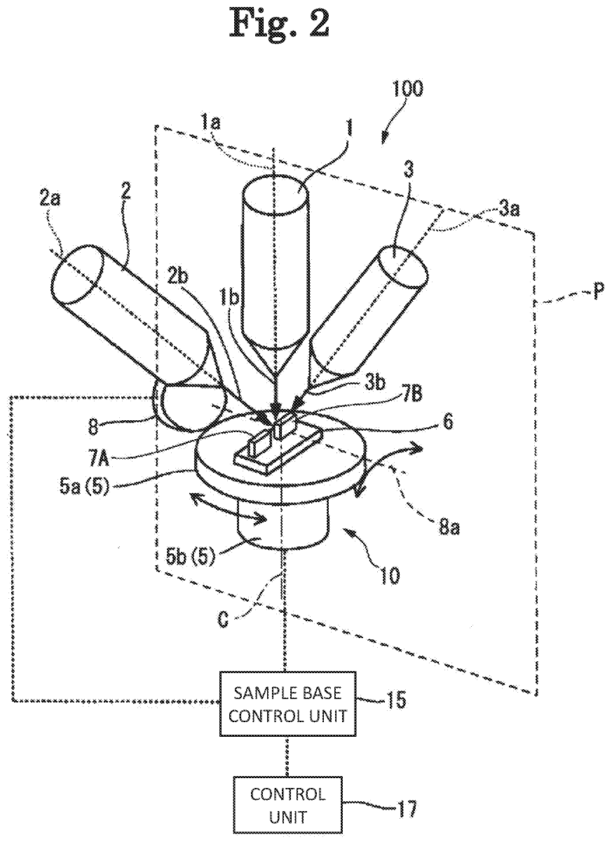

FIG. 1 is a schematic diagram showing an example of a configuration of a charged particle beam apparatus according to the first embodiment of the present invention. FIG. 2 is a schematic perspective view showing a configuration of main parts of the charged particle beam apparatus according to the first embodiment of the present invention. Since each drawing is a schematic view, the shape and dimensions are exaggerated (the same applies to the following drawings).

As shown in FIG. 1, a charged particle beam apparatus 100 of the present embodiment includes a sample chamber 9, a sample stage 10, an FIB lens barrel 1 (charged particle beam lens barrel), an EB lens barrel 2 (charged particle beam lens barrel), a GIB lens barrel 3 (charged particle beam lens barrel), a gas gun 19, and a sample holder 6.

Here, “FIB” is an abbreviation standing for Focused Ion Beam, “EB” is an abbreviation standing for Electron Beam. “GIB” is an abbreviation standing for Gas Ion Beam.

The sample chamber 9 accommodates therein samples 7A and 7B to be processed, observed, and/or analyzed by the charged particle beam apparatus 100. The samples 7A and 7B are minute thin pieces. In FIG. 1, the size of the samples 7A and 7B is greatly exaggerated for easy viewing. The sample chamber 9 is connected to a vacuum exhaust apparatus (not shown) for changing and maintaining a degree of vacuum inside the sample chamber 9.

The sample chamber 9 may be provided with a load lock chamber (not shown) such that the sample can be carried in and out without changing the internal atmosphere and the vacuum state.

The sample stage 10 is built in the sample chamber 9. In the sample chamber 9, the FIB lens barrel 1, the EB lens barrel 2, and the GIB lens barrel 3 are disposed at positions facing the sample stage 10.

The sample stage 10 is configured to include a rotation stage 5. In the present embodiment, the sample stage 10 includes a 5-axis moving stage.

The rotation stage 5 is disposed on the top of the sample stage 10. Below the rotation stage 5, an XYZ stage (not shown) and a tilting stage (not shown) are disposed.

As shown in FIG. 2, a tilting stage includes a tilting drive unit 8 for tilting the sample stage 10 by turning the rotation stage 5 about an axis 8a in a horizontal plane.

The rotation stage 5 includes a sample base 5a and a rotation drive unit 5b. The sample base 5a is configured to be able to detach or attach a sample holder 6 to be described later. The rotation drive unit 5b rotates the sample base 5a about a rotation axis C. When the tilting stage (not shown) in the sample stage 10 is at a reference position of tilt, the rotation axis C is parallel to a vertical axis.

An upper surface of the sample base 5a is provided with an attachment/detachment mechanism (not shown) for positioning and attaching/detaching the sample holder 6 to be described later.

The rotation drive unit 5b includes, for example, a rotation support portion (not shown) for rotatably holding the sample base 5a, a motor (not shown) for supplying a driving force for rotating the sample base 5a, and a transmission mechanism for transmitting the driving force of the motor to the sample base 5a.

As shown in FIG. 2, the FIB lens barrel 1 is disposed above the sample stage 10 to face the sample stage 10. In the present embodiment, as an example, the FIB lens barrel 1 is disposed parallel to the vertical axis.

The FIB lens barrel 1 emits an FIB 1b as a first charged particle beam along an FIB irradiation axis 1a parallel to the vertical axis. The FIB lens barrel 1 includes, for example, a liquid metal ion source.

The EB lens barrel 2 is disposed above the sample stage 10 along an axis tilted with respect to the vertical axis. The EB lens barrel 2 emits an EB 2b as a second charged particle beam along an EB irradiation axis 2a tilted with respect to the vertical axis.

The GIB lens barrel 3 is disposed above the sample stage 10 along an axis tilted in a direction different from that of the EB lens barrel 2 with respect to the vertical axis. The GIB lens barrel 3 emits a GIB 3b as a third charged particle beam along a GIB irradiation axis 3a tilted in a direction different from that of the EB lens barrel 2 with respect to the vertical axis.

The GIB lens barrel 3 includes, for example, a PIG gas ion source. Examples of the gas ion source include helium, argon, xenon, or oxygen as an ion source gas.

The FIB irradiation axis 1a intersects the GIB irradiation axis 3a at a predetermined position above the sample stage 10 on a plane P including the axis 8a and the vertical axis. The EB irradiation axis 2a intersects the FIB irradiation axis 1a and the GIB irradiation axis 3a at the predetermined position where the FIB irradiation axis 1a intersects the GIB irradiation axis 3a, that is, the FIB 1b, the EB 2b, and the GIB 3b intersect one another at the predetermined position.

The charged particle beam apparatus 100 further includes a secondary electron detector 4 for detecting secondary electrons generated from the sample 7A (7B) by irradiation with the EB 2b, the FIB 1b, or the GIB 3b. Further, the charged particle beam apparatus 100 may include a backscattered electron detector for detecting backscattered electrons generated from the sample by irradiation with the EB 2b.

As shown in FIG. 1, the gas gun 19 supplies an etching gas near irradiation regions of the FIB 1b, the EB 2b, and the GIB 3b. Examples of the etching gas include halogen gases such as a chlorine gas, a fluorine-based gas (such as xenon fluoride and fluorine carbide), and an iodine gas. When the gas gun 19 supplies an etching gas reacting with the material of the sample 7A (7B) to the irradiation region of the FIB 1b, the EB 2b, or the GIB 3b, the sample 7A (7B) is subjected to gas-assisted etching by the FIB 1b, the EB 2b, or the GIB 3b. Particularly in the gas-assisted etching by the EB 2b, etching can be performed without damaging the sample 7A (7B) by ion sputtering.

The sample holder 6 includes two tilting bases which turn the samples 7A and 7B about a first turning axis and a second turning axis respectively, and a tilting stage which turns the two tilting bases about a third turning axis orthogonal to the first turning axis and the second turning axis. A specific configuration example of the sample holder 6 will be described later.

Next, a configuration of a control system of the charged particle beam apparatus 100 will be described.

As shown in FIG. 1, the charged particle beam apparatus 100 includes a sample stage control unit 15, a sample holder control unit 40, an FIB control unit 11, an EB control unit 12, a GIB control unit 13, an image forming unit 14, and a control unit 17.

The sample stage control unit 15 is communicably connected to each stage drive unit of the sample stage 10. The stage drive unit includes the rotation drive unit 5b and the tilting drive unit 8.

The sample stage control unit 15 moves each stage of the sample stage 10 by controlling each stage drive unit based on a control signal from the control unit 17 to be described later. For example, under the control of the sample stage control unit 15, the rotation drive unit 5b drives the sample base 5a to rotate. For example, under the control of the sample stage control unit 15, the tilting drive unit 8 drives a tilting stage (not shown) to tilt.

The sample holder control unit 40 is communicably connected to a drive unit in the sample holder 6 via a wiring (not shown) when the sample holder 6 to be described later is disposed on the sample base 5a.

The sample holder control unit 40, in a state of being connected to the sample holder 6, tilts the tilting base and the tilting stage of the sample holder 6 based on a control signal from the control unit 17 to be described later. Accordingly, the sample holder control unit 40 can change the tilting of the samples 7A and 7B held on the sample holder 6 with respect to the rotation axis C in a biaxial direction.

The FIB control unit 11 controls FIB irradiation from the FIB lens barrel 1 based on a control signal from the control unit 17 to be described later.

The EB control unit 12 controls EB irradiation from the EB lens barrel 2 based on a control signal from the control unit 17 to be described later.

The GIB control unit 13 controls GIB irradiation from the GIB lens barrel 3 based on a control signal from the control unit 17 to be described later.

The image forming unit 14, for example, forms an SEM image based on a signal obtained by the EB control unit 12 controlling the EB to perform scanning and a secondary electron signal detected by the secondary electron detector 4. Further, the image forming unit 14 forms a scanning ion microscope (SIM) image based on a signal obtained by the FIB control unit 11 controlling the FIB to perform scanning and a secondary electron signal detected by the secondary electron detector 4.

The SEM image and the SIM image formed by the image forming unit 14 are sent to the control unit 17 to be described later.

The control unit 17 is communicably connected to the sample stage control unit 15, the sample holder control unit 40, the FIB control unit 11, the EB control unit 12, the GIB control unit 13, the image forming unit 14, an input unit 16, and a display unit 18.

The input unit 16 is a device for performing an operation input by an operator of the charged particle beam apparatus 100. The operation input which is input to the input unit 16 is sent to the control unit 17.

The display unit 18 is a device for displaying information sent from the control unit 17.

The control unit 17 analyzes the operation input sent from the input unit 16 and generates a control signal for overall control over the charged particle beam apparatus 100. The control unit 17 sends, as necessary, the generated control signal to the sample stage control unit 15, the sample holder control unit 40, the FIB control unit 11, the EB control unit 12, the GIB control unit 13, and the image forming unit 14.

The control unit 17 sends information on observation images such as an SEM image and an SIM image sent from the image forming unit 14 and information on various control conditions of the charged particle beam apparatus 100 to the display unit 18, and displays the above information on the display unit 18.

Specific control performed by the control unit 17 will be described later together with the operation of the charged particle beam apparatus 100.

The configuration of the control system including the sample stage control unit 15, the sample holder control unit 40, the FIB control unit 11, the EB control unit 12, the GIB control unit 13, the image forming unit 14, and the control unit 17 described above may be configured by appropriate hardware and a computer including a CPU, a memory, an input/output interface, an external storage device, and the like. A part or all of each control function of the control system may be implemented by a computer executing a control program for implementing each control function.

Next, a detailed configuration of the sample holder 6 will be described.

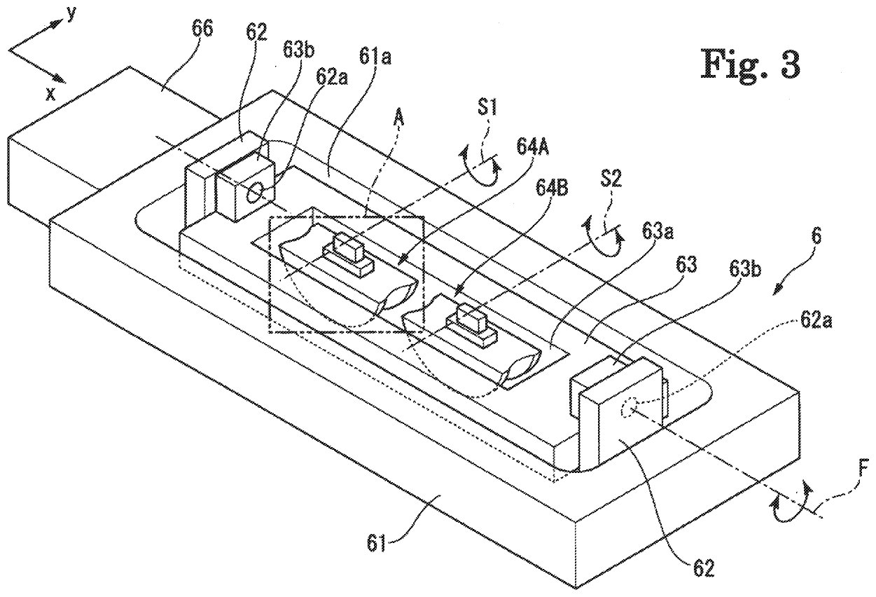

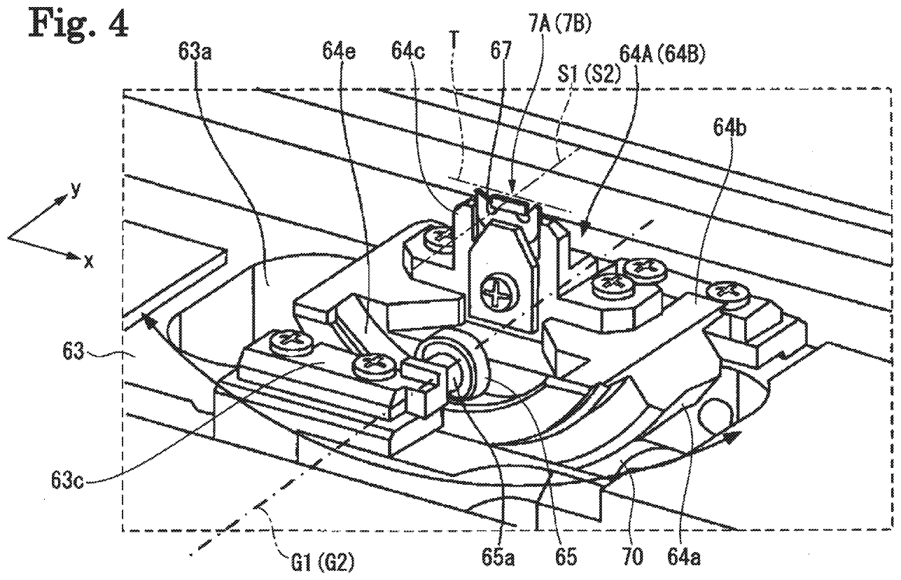

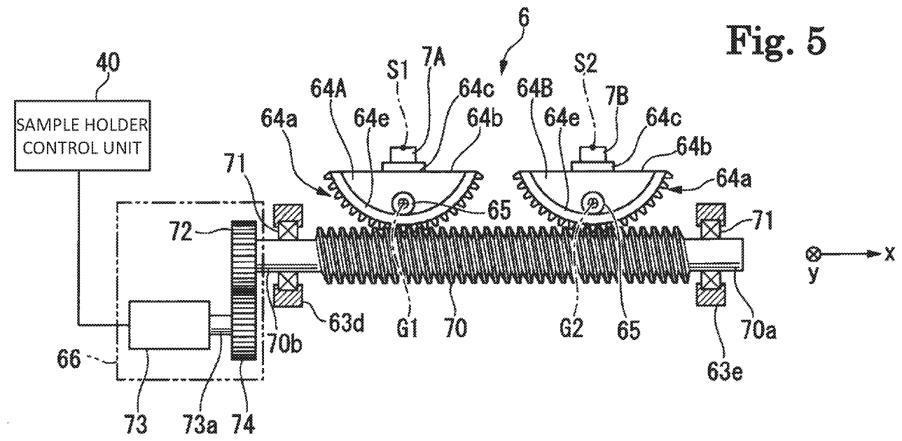

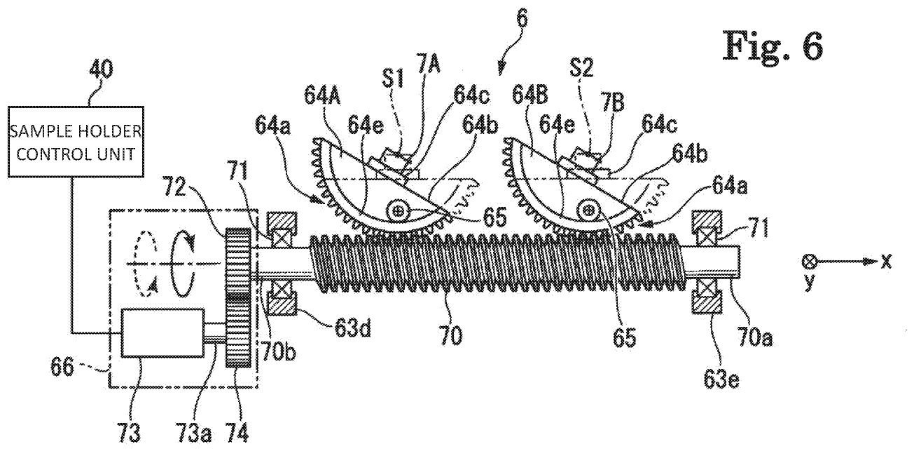

FIG. 3 is a schematic perspective view showing a main configuration of the sample holder in the charged particle beam apparatus according to the first embodiment of the present invention. FIG. 4 is a detailed diagram of a portion A in FIG. 3. FIG. 5 is a schematic front view showing an example of an internal structure of the sample holder in the charged particle beam apparatus according to the first embodiment of the present invention. FIG. 6 is an operation illustrative diagram of the sample holder in the charged particle beam apparatus according to the first embodiment of the present invention.

As shown in FIG. 3, the sample holder 6 includes a base 61, support portions 62, a turning base 63, a tilting base 64A (first tilting base), a tilting base 64B (second tilting base), and a drive unit 66. However, only the main configuration is schematically drawn in FIG. 3 for easy viewing.

Hereinafter, in a case of describing the configuration of the sample holder 6, an xy coordinate system may be referred to corresponding to the disposing posture of the sample holder 6 on the sample based 5a.

The x-axis and y-axis in the xy coordinate system are orthogonal to each other. The x-axis and y-axis are fixed on the upper surface of the sample base 5a.

The base 61 can be placed on the upper surface of the sample base 5a, and has an outer shape capable of being positioned in the biaxial direction within the upper surface of the sample base 5a by a positioning mechanism (not shown). In the example shown in FIG. 3, the base 61 has a rectangular plate-like outer shape which is long in the x-axis direction. For example, side surfaces of the base 61 in the x-axis direction and the y-axis direction may be used as a positioning unit with the positioning mechanism.

A recess 61a having a substantially rectangular shape in a plan view is formed in an upper surface of the base 61.

The support portions 62 are provided upright at both ends in the x-axis direction in the recess 61a. Each support portion 62 is provided with a support shaft 62a extending coaxially with an axis F (third turning axis) parallel to the x-axis.

In the recess 61a, a turning base 63 (tilting stage) having a rectangular shape in a plan view is disposed between the support portions 62. At both end portions of the turning base 63 in the x-axis direction, bearing portions 63b rotatably connected to the support shafts 62a of the support portions 62 are provided above the turning base 63, respectively. Accordingly, the turning base 63 is supported to be turnable about the axis F.

The turning base 63 is connected to a turning base drive unit (not shown) via a transmission mechanism (not shown). The turning base drive unit is communicably connected to the sample holder control unit 40. The turning base drive unit turns the turning base 63 about the axis F based on a control signal from the sample holder control unit 40. When the turning base 63 is turned about the axis F, the turning base 63 is tilted in the y-axis direction.

A hole portion 63a opening upward is formed in a center portion of the turning base 63 in a plan view. The tilting bases 64A and 64B are accommodated in the hole portion 63a side by side in the x-axis direction. Positions of the tilting bases 64A and 64B in the y-axis direction are positioned by a positioning unit (not shown) on an inner peripheral portion of the hole portion 63a.

The tilting bases 64A and 64B may have different shapes, but in the present embodiment, they have the same shape.

FIG. 4 shows an example of a detailed configuration of the tilting base 64A. Hereinafter, the structure of the tilting base 64A common to the tilting base 64B will be described.

As shown in FIG. 4, the tilting base 64A has a substantially half-moon shape when viewed from the y-axis direction. A worm wheel 64a is provided on an arc-shaped outer peripheral portion of the tilting base 64A.

A guide groove 64e concentrically curved with a pitch circle of the worm wheel 64a is formed on a side surface of the tilting base 64A in the y-axis direction.

A sample holding portion 64c for holding the sample 7A via a TEM grid 67 is disposed on a plane portion 64b of the tilting base 64A facing the worm wheel 64a.

Similarly, a sample holding portion 64c for holding the sample 7B via a TEM grid 67 is disposed on the plane portion 64b of the tilting base 64B facing the worn wheel 64a.

The sample holding portion 64c disposed on the tilting base 64A constitutes a first sample holding portion. The sample holding portion 64c disposed on the tilting base 64B constitutes a second sample holding portion.

Inside the turning base 63, a worm 70 (a third gear, a driving force supplier) is disposed below the tilting base 64A.

As shown in FIG. 5, the worm 70 extends parallel to the x-axis, and meshes with the worn wheels 64a of the tilting bases 64A and 64B from below.

Both ends of the worm 70 in the axial direction are supported by bearing bases 63d and 63e inside the turning base 63 via bearings 71, respectively. The worm 70 is rotatably supported by each bearing 71.

An inter-axis distance between the worm 70 and each worm wheel 64a is regulated by each roller 65 in contact with each guide groove 64e in a rollable manner. As shown in FIG. 4, the roller 65 in contact with the guide groove 64e of the tilting base 64A is rotatably supported by the support shaft 65a extending in the y-axis positive direction from the support portion 63c on the upper surface of the turning base 63. Thus, the roller 65 in contact with the guide groove 64e of the tilting base 64A is rotatable about an axis G1 parallel to the y-axis.

As shown in FIG. 5, similar to the roller 65 in contact with the guide groove 64e of the tilting base 64A, the roller 65 in contact with the guide groove 64e of the tilting base 64B is also rotatably supported by the turning base 63 (not shown) and the support shaft 65a (not shown). However, the roller 65 in contact with the guide groove 64e of the tilting base 64B is rotatable about an axis G2 parallel to the axis G1.

With such a configuration, when the worm 70 is driven to rotate, the tilting bases 64A and 64B turn in a state where the inter-axis distance between the worm 70 and each worm wheel 64a is maintained by each roller 65. As shown in FIG. 6, as a result, the tilting bases 64A and 64B turn about an axis S1 (first turning axis) and an axis S2 (second turning axis) parallel to the y-axis through a pitch circle center of each worm wheel 64a. The worm wheel 64a of the tilting base 64A is a first worm wheel and constitutes a first gear having the axis S1 which is the first turning axis as the pitch circle center. The worm wheel 64a of the tilting base 64B is a second worm wheel and constitutes a second gear having the axis S2 which is the second turning axis as the pitch circle center.

Accordingly, the plane portions 64b of the tilting bases 64A and 64B are tilted in the x-axis direction together with the rotation of the worm 70. When the rotation direction of the worm 70 is switched, the tilting bases 64A and 64B tilt in the opposite direction.

In the present embodiment, since the tilting bases 64A and 64B have the same shape, tilting directions, tilting speeds, and tilting angles of the tilting bases 64A and 64B are the same.

The drive unit 66 has a drive source for supplying a driving force to the sample holder 6. The drive unit 66 may be disposed at a position on the sample holder 6, but in the present embodiment, as shown in FIG. 3, the drive unit 66 is attached to one end of the base 61 in the x-axis direction.

The drive unit 66 in the present embodiment includes two drive sources for supplying a driving force to the turning base 63 and the tilting bases 64A and 64B independently of each other.

FIG. 5 shows an example of a configuration for supplying a driving force to the tilting bases 64A and 64B.

The drive unit 66 includes a drive motor 73 (driving force supplier) and gears 74 and 72 (driving force supplier).

The drive motor 73 is a drive source for driving the tilting bases 64A and 64B. The type of the drive motor 73 is not limited as long as it is an appropriate motor capable of performing forward and reverse rotation.

The drive motor 73 is communicably connected to the sample holder control unit 40. The operation of the drive motor 73 is controlled according to a control signal from the sample holder control unit 40.

The gear 74 is coaxially attached to an output shaft 73a of the drive motor 73.

The gear 72 is fixed coaxially to a central axis of the worm 70 at an end portion of the worm 70. The gear 72 meshes with the gear 74.

As the gears 74 and 72, a spur gear, a helical gear, or the like may be used. The gears 74 and 72 constitute a transmission mechanism for transmitting the driving force of the drive motor 73 to the worm 70.

However, the gears 74 and 72 are examples of the transmission mechanism. The transmission mechanism may include an appropriate speed reduction mechanism. The transmission mechanism may include a transmission mechanism other than the gear.

In the example shown in FIG. 5, the output shaft 73a of the drive motor 73 and the central axis of the worm 70 are parallel to each other. However, a gear which transmits a driving force in a state where the output shall 73a of the drive motor 73 intersects the central axis of the worm 70 may be used for the transmission mechanism.

With such a configuration, the sample holder 6 is a biaxial tilting stage in which the turning base 63 and the plane portions 64b of the tilting bases 64A and 64B tilt in the y-axis direction by the turning about the axis F and the plane portions 64b of the tilting bases 64A and 64B tilt in the x-axis direction by the turning about the axis S1 and the axis S2.

The worm 70, the gears 74 and 72, and the drive motor 73 constitute a driving force supplier which supplies a driving force for turning the tilting bases 64A and 64B together with each other.

Here, the TEM grid 67 and the samples 7A and 7B will be described.

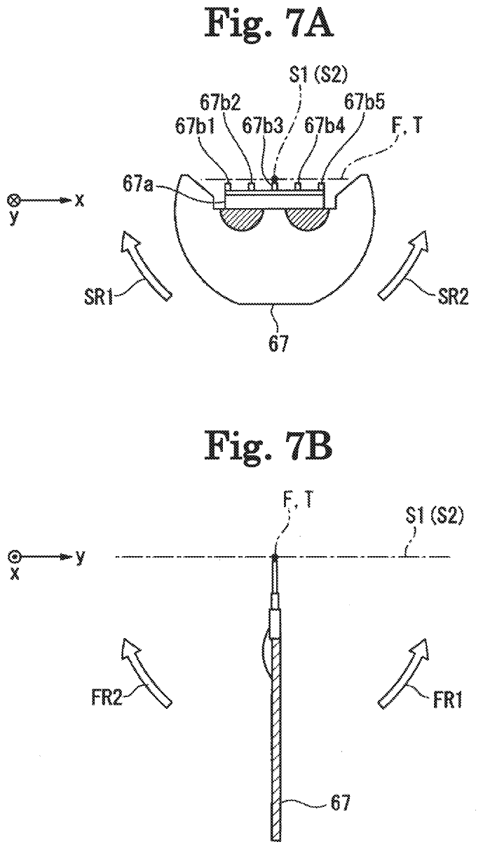

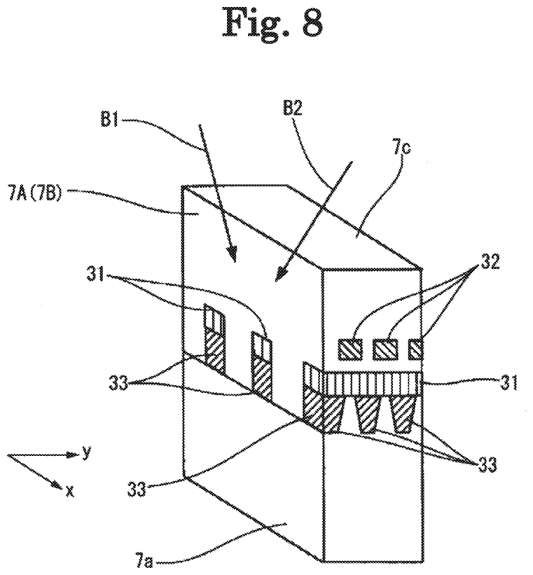

FIGS. 7A and 7B show a schematic front view and side view showing the holding form of the sample in the charged particle beam apparatus according to the first embodiment of the present invention. FIG. 8 is a schematic perspective view showing a relationship between the sample and a processing direction in the charged particle beam apparatus according to the first embodiment of the present invention.

As shown in FIGS. 7A and 7B, the TEM grid 67 is made of a thin plate, and a sample holding base 67a is formed at the center. Five columns 67b1, 67b2, 67b3, 67b4, and 67b5 are formed on the sample holding base 67a.

Examples of the sample attached to the upper part of the columns 67b1 to 67b5 include a minute thin sample 7A (7B) shown in FIG. 8.

The sample 7A (7B) is formed by cutting out a part of a semiconductor device, for example. The sample 7A (7B) includes structures 31, 32, and 33. The structures 31 and 33 are exposed on a cross section 7a as an observation surface. The sample 7A (7B) is attached to the columns 67b1 to 67b5 such that the FIB, the EB, and the GIB are emitted from an upper surface 7c side.

In the present embodiment, when the tilting base 64A (64B) is at a reference position, the sample 7A (7B) is attached such that a normal direction of the cross section 7a (the thickness direction of the sample 7A (7B)) is substantially the y-axis direction.

In the present embodiment, the sample 7A on the column 67b3 is disposed at an intersection of the axis F and the axis S1. Similarly, the sample 7B on the column 67b3 is disposed at an intersection of the axis F and the axis S2.

Next, the operation of the charged particle beam apparatus 100 will be described focusing on the effect of the sample holder 6.

The charged particle beam apparatus 100 can perform at least one of processing, observation, and analysis (hereinafter, may be referred to as “processing or the like”) on the samples 7A and 7B according to an operation input from the input unit 16.

The samples 7A and 7B are shaped in advance to an appropriate size and then held on, for example, the TEM grid 67. For example, the TEM grid 67 holding the sample 7A is held by the sample holding portion 64c on the tilting base 64A of the sample holder 6 as shown in FIG. 4. At this time, the TEM grid 67 is held by the sample holding portion 64c such that a straight line T connecting the upper surface of the sample 7A is substantially parallel to the axis F (see FIGS. 7A and B) and the straight line T is positioned at substantially the same height as the axis S. Similarly, the TEM grid 67 holding the sample 7B is held by the sample holding portion 64c on the tilting base 64B of the sample holder 6.

Such a disposing operation of the TEM grid 67 is performed in a state where the sample holder 6 is carried out of the charged particle beam apparatus 100. Thus, precise alignment can be obtained by using an appropriate jig, a measuring device, or the like. Further, such a disposing operation of the TEM grid 67 may be performed by an operator different from the operator of the charged particle beam apparatus 100.

In parallel with this, preparation for operation of the charged particle beam apparatus 100 is performed. For example, the control unit 17 sends a control signal to the sample stage control unit 15, and the sample stage 10 initializes the position of each stage to the reference position for each movement.

Thereafter, the sample holder 6 holding the samples 7A and 7B is disposed on the sample base 5a of the sample stage 10 of the charged particle beam apparatus 100. When the sample holder 6 is fixed to the sample base 5a in a positioning state, the sample chamber 9 is evacuated. However, when the charged particle beam apparatus 100 includes a load lock chamber, evacuation may be completed during the preparing for operation. In this case, the operator can install the sample holder 6 on the sample base 5a through the load lock chamber while the sample chamber 9 is maintained in a vacuum state.

Thereafter, the control unit 17 controls each portion of the charged particle beam apparatus 100 based on an operation input from the input unit 16 of the operator, and thereby the samples 7A and 7B are processed. Hereinafter, an example in which the sample 7B is processed after the sample 7A is processed will be described.

For example, the operator causes the display unit 18 to display the SEM image or SIM image of the sample 7A. The operator sets, for example, an irradiation region of the FIB 1b based on an observation image such as an SEM image or an SIM image displayed on the display unit 18. The operator inputs a processing frame for setting an irradiation region on the observation image displayed on the display unit 18 through the input unit 16.

When the operator inputs an instruction to start the processing to the input unit 16, an irradiation region and a processing start signal are transmitted from the control unit 17 to the FIB control unit 11, and the FIB is emitted from the FIB control unit 11 onto a designated irradiation region of the sample 7A. Accordingly, the FIB 1b is emitted onto the irradiation region input by the operator.

In the charged particle beam apparatus 100, in order to perform SEM observation on the sample 7A (7B) being processed by the FIB 1b, as shown in FIG. 2, the FIB irradiation axis 1a intersects the EB irradiation axis 2a. The operator drives the sample stage 10 by an operation input from the input unit 16 such that the sample 7A (7B) is aligned at a position where the FIB irradiation axis 1a intersects the EB irradiation axis 2a.

After the alignment, when an operation input for rotating the rotation stage 5 is performed, a control signal is sent from the control unit 17 to the sample stage control unit 15. The rotation stage 5 is rotated under the control of the sample stage control unit 15. As a result, the sample 7A (7B) is rotated about the rotation axis C in a state where the SEM image can be observed.

Further, when an operation input for turning the tilting base 64A (64B) of the sample holder 6 about the axis F or the axis S1 (S2) is performed, a control signal is sent from the control unit 17 to the sample holder control unit 40. The tilting base 64A (64B) of the sample holder 6 is tilted in the y-axis direction or the x-axis direction under the control of the sample holder control unit 40. As a result, the sample 7A (7B) is tilted in the y-axis direction or the x-axis direction in a state where the SEM image can be observed. Here, the tilting in the x-axis direction is a tilting caused by turning in a direction represented by arrows SR1 and SR2 in FIG. 7A. The tilting in the y-axis direction is a tilting caused by turning in a direction represented by arrows FR1 and FR2 in FIG. 7B.

Thus, in the charged particle beam apparatus 100, after aligning the sample 7A (7B), it is easy and highly accurate to rotate the sample 7A (7B) about the rotation axis C and tilt the same in the x-axis direction or the y-axis direction in a eucentric state.

Thus, according to the charged particle beam apparatus 100, the processing which prevents the curtain effect can be performed easily.

For example, as shown in FIG. 8, the position of the sample 7A (7B) is moved by the sample stage 10 and the sample holder 6, and the charged particle beam is emitted from the direction of an arrow B1 to process the cross section 7a. In this case, in the cross section 7a, the etching rate is different between a portion where the structures 31 and 33 are exposed and a portion where other semiconductors are exposed. An unevenness is formed on the cross section 7a. This phenomenon is known as the so-called curtain effect.

When SEM observation is performed on the cross section 7a on which the unevenness is formed, the observed image includes streaks caused by the unevenness. Since these streaks are formed by ion beam processing, these streaks are not semiconductor device structures or defects. When occurring in the observed image, the streaks may be indistinguishable from structures of the semiconductor device or defect.

However, according to the charged particle beam apparatus 100, by tilting the tilting base 64A (64B) in the x-axis direction from this state, the irradiation direction of the charged particle beam can be easily changed as shown by the arrow B2 while maintaining the eucentric state. For example, even when the cross section 7a is tilted in the y-axis direction due to an attaching error of the TEM grid 67, the rotation in the plane of the cross section 7a can be performed by the operator performing an operation input for finely adjusting the tilting in the y-axis direction while observing the cross section 7a.

Thus, the unevenness generated by the curtain effect can be reduced by repeating a finishing processing of checking the charged particle beam from a plurality of directions along the cross section 7a.

When all necessary processing, observation and analysis for sample 7A are complete, the operator performs an operation input for driving the sample stage 10 and moves the sample holder 6 in the x-axis direction by a separation distance from the sample 7B to the sample 7A. Since in the sample holder 6, the separation distance from the sample 7B to the sample 7A is determined as a disposed pitch in the x-axis direction of the tilting bases 64A and 64B, such a movement operation can be automatically controlled by the control unit 17 based on an operation input of movement start by the operator.

When the movement of the sample holder 6 in the x-axis direction is completed, the sample 7B is positioned in the irradiation region of the charged particle beam instead of the sample 7A. Thus, the operator can start processing, observing, and analyzing the sample 7B immediately after the sample holder 6 is moved. However, when the posture of the sample 7B needs to be finely adjusted due to the attaching error of the sample 7B, the operator may finely adjust the position of the sample 7B with respect to the irradiation region by driving the sample stage 10 or the sample holder 6 while observing the sample 7B before starting the processing.

When the sample 7B is disposed in the irradiation region of the charged particle beam in the same manner as the sample 7A, the sample 7B is processed in the same manner as the sample 7A.

According to the charged particle beam apparatus 100, the tilting base 64B holding the sample 7B in the sample holder 6 is driven in the same manner as the tilting base 64A by the drive motor 73 for driving the tilting base 64A. Further, the tilting bases 64A and 64B are both disposed on the turning base 63. Thus, the tilting base 64B can be driven by the drive unit 66 in the same manner as the tilting base 64A. Thus, when processing the sample 7B, the processing which prevents the curtain effect similar to that of the sample 7A can be performed. Particularly when the shapes of the samples 7A and 7B are the same, the sample holder control unit 40 can also perform drive control during processing of the sample 7B by a drive control program for processing the sample 7A.

When all necessary processing, observation and analysis for sample 7B are complete, the operator takes the samples 7A and 7B out of the sample stage 10 by carrying out the sample holder 6 from the sample chamber 9. Further, when it is necessary to process another sample, the above processing or the like is performed by carrying another sample holder 6 holding another sample into the sample chamber 9 in the same manner as described above.

Particularly when the charged particle beam apparatus 100 includes a load lock chamber, the sample chamber 9 is kept in a vacuum state during such a carrying-out operation. In this case, the operator can dispose the sample holder 6 holding the samples 7A and 7B whose positions are adjusted in advance outside the apparatus on the sample stage 10 without opening the sample chamber 9 to the atmosphere. Further, the operator can replace the sample holder 6 in the sample chamber 9 with another sample holder 6 without opening the sample chamber 9 to the atmosphere.

Thus, the operator can continue the processing on the other samples 7A and 7B using the charged particle beam apparatus 100 by immediately carrying the other sample holder 6 into the sample chamber 9.

As described above, according to the charged particle beam apparatus 100, a plurality of samples 7A and 7B positioned and held on the sample holder 6 can be carried into the sample chamber 9 and carried out from the sample chamber 9. Thus, by using the charged particle beam apparatus 100, the operator can quickly disposed and replace the sample when processing a plurality of samples. In addition, the charged particle beam apparatus can form a sample safely and efficiently even in a case of processing a plurality of samples.

The charged particle beam apparatus 100 can process the samples 7A and 7B substantially continuously only by leaving a time for moving the samples 7A and 7B held on the sample holder 6 to the irradiation region of the charged particle beam. Thus, the throughput in processing the samples 7A and 7B and the operation efficiency of the charged particle beam apparatus 100 can be improved.

Particularly when the charged particle beam apparatus 100 includes a load lock chamber, since the sample holder 6 is carried out without releasing the vacuum state of the sample chamber 9, the sample replacement time accompanying the replacement of the sample holder 6 can be further shortened.

According to the charged particle beam apparatus 100, when a complex processing such as finishing which prevents the curtain effect is performed, since a plurality of samples are disposed on the sample holder 6 including the tilting bases 64A and 64B interlocking with each other, a control program for the sample holder 6 in each sample can be shared.

Further, since the tilting bases 64A and 64B are interlocked with each other in the sample holder 6, both of the tilting bases 64A and 64B are driven by the drive motor 73, which is a single drive source. Thus, the component cost of the sample holder 6 is reduced as compared with a case where the tilting bases 64A and 64B are driven by different drive sources. Further, the sample holder 6 can be easily made compact.

### Second Embodiment

A charged particle beam apparatus according to a second embodiment of the present invention will be described.

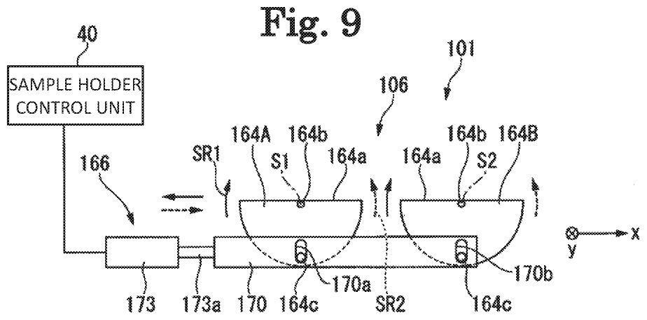

FIG. 9 is a schematic front view showing an example of an internal structure of a sample holder in the charged particle beam apparatus according to the second embodiment of the present invention.

As shown in FIG. 9, a charged particle beam apparatus 101 according to the present embodiment includes a sample holder 106 instead of the sample holder 6 of the first embodiment. Further, as shown in FIG. 9, the charged particle beam apparatus 101 includes the sample holder 106 instead of the sample holder 6 of the first embodiment.

Hereinafter, the description will be given centering on differences from the first embodiment.

As shown schematically in FIG. 9, the sample holder 106 includes a tilting base 164A (first tilting base), a tilting base 164B (second tilting base), and a drive rod 170 (driving force supplier) instead of the tilting bases 64A and 64B and the worm 70 in the sample holder 6.

The tilting bases 164A and 164B have the same shape. The outer shape of the tilting base 164A (164B) is a substantially half-moon shape when viewed from the y-axis direction, and a plane portion 164a is formed at a position facing the arc portion. A sample holding portion 64c (not shown) is disposed on the plane portion 164a, similarly to the plane portion 64b of the tilting base 64A (64B) of the first embodiment.

The tilting bases 164A and 164B are accommodated in the hole portion 63a (not shown) side by side in the x-axis direction. Positions of the tilting bases 164A and 164B in the y-axis direction are positioned by a positioning unit (not shown) on the inner peripheral portion of the hole portion 63a.

The tilting base 164A (164B) includes a turning support portion 164b and an engaging portion 164c.

The turning support portion 164b supports the tilting base 164A (164B) with respect to the turning base 63 (not shown) to be turnable about the axis S1 (S2) similar to that of the first embodiment. The configuration of each turning support portion 164b is not particularly limited as long as the tilting bases 164A and 164B can be supported to be turnable about the axis S1 and the axis S2, respectively.

For example, the turning support portion 164b in FIG. 9 schematically represents a mechanism including a turning support shaft coaxial with the axis S1 (S2) and a bearing provided on the turning base 63.

For example, the turning support portion 164b may he configured by a sliding engagement portion formed on the tilting base 164A (164B) and the turning base 63 along an arc-shaped trajectory concentric with the axis S1 (S2).

The engaging portion 164c is connected to the drive rod 170 for converting a driving force transmitted by the drive rod 170, to be described later into a turning force about the axis S1 (S2). As the engaging portion 164c, an appropriate protrusion, hole, groove, or the like may be used according to the configuration of the drive rod 170.

In the example schematically shown in FIG. 9, the engaging portion 164c is configured by a pin member protruding in the y-axis direction in an outer peripheral side region of the tilting base 164A (164B).

The drive rod 170 is a rod-shaped member extending in the x-axis direction. The drive rod 170 is supported by a linear guide provided on the turning base 63 (not shown) so as to be able to advance and retreat in the x-axis direction.

The drive rod 170 includes engagement portions 170a connected to the respective engaging portions 164c in a state of being in contact with the respective engaging portions 164c of the tilting bases 164A and 164B in the x-axis direction.

As the engagement portion 170a, a configuration appropriate for contacting and engaging the engaging portion 164c in the x-axis direction such that the engaging portion 164c is freely moved in a direction orthogonal to the x-axis and the y-axis may be used.

For example, when the engaging portion 164c is a pin member as in the example schematically shown in FIG. 9, the engagement portion 170a may be configured by a long hole which penetrates in the y-axis direction in the drive rod 170 and is long in the direction orthogonal to the x-axis and the y-axis. In this case, the engaging portion 164c formed of a pin member is fitted to the engagement portion 170a formed of a long hole so as to be slidable in a longitudinal direction.

For example, when the engaging portion 164c is configured by a hole portion, the engagement portion 170a may be configured by a protrusion such as a pin.

The drive unit 166 includes a drive source 173 (driving force supplier) instead of the drive motor 73 and the gears 74 and 72 of the drive unit 66 of the first embodiment. The drive source 173 is communicably connected to the sample holder control unit 40. The drive source 173 advances and retreats the drive rod 170 in the x-axis direction based on a control signal from the sample holder control unit 40.

The configuration of the drive source 173 is not particularly limited as long as a driving force for driving the drive rod 170 can be supplied. In FIG. 9, as an example, the drive source 173 is configured by a linear motor for driving an output shaft 173a in the axial direction. The output shaft 173a is disposed along the x-axis direction and is connected to the end of the drive rod 170.

However, the output shaft 173a of the drive source 173 is not directly connected to the drive rod 170, but may be connected to the drive rod 170 via a transmission mechanism such as a cam, a link, or a gear.

For example, the drive source 173 may be configured by a rotation motor and a transmission mechanism for converting a rotational motion into a linear motion.

According to the sample holder 106, when the output shaft 173a of the drive source 173 moves in the x-axis negative (positive) direction (see the solid line (broken line) arrow in the drawing), the drive rod 170 moves in the same direction. Accordingly, a driving force in the same direction is transmitted to the tilting bases 164A and 164B via the engaging portion 164c engaged with the engagement portion 170a.

When the driving force in the x-axis negative (positive) direction is transmitted from the engaging portion 164c, the tilting base 164A (164B) turns about the axis S1 (S2) in the direction of the arrow SR1 (SR2). As a result, each plane portion 164a of the tilting bases 164A and 164B is tilted in the x-axis direction together with the sample holding portion 64c (not shown).

The sample holder 106 in the present embodiment is different from the sample holder 6 in the first embodiment in the drive mechanism for tilting the tilting bases 164A and 164B. However, similarly to the first embodiment, the sample holder 106 can tilt the tilting bases 164A and 164B together with each other in the x-axis direction based on the control signal from the sample holder control unit 40.

Thus, according to the charged particle beam apparatus 101, the sample can be quickly disposed and replaced, similarly to the first embodiment. In addition, the charged particle beam apparatus can form a sample safely and efficiently even in a case of processing a plurality of samples.

Further, according to the present embodiment, since the driving force is transmitted to the tilting bases 164A and 164B via the drive rod 170, the configuration of the tilting bases 164A and 164B is simplified compared with a case where the worm wheel is formed. Thus, according to the sample holder 106, the manufacturing cost of the sample holder 106 can be reduced, or the configuration of the sample holder 106 can be made compact.

### Third Embodiment

A charged particle beam apparatus according to a third embodiment of the present invention will be described.

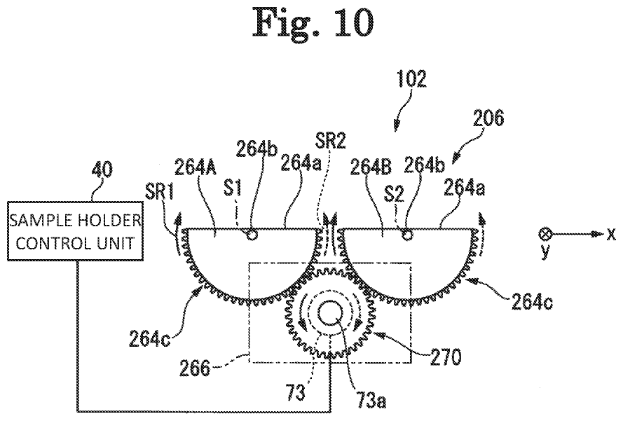

FIG. 10 is a schematic front view showing an example of an internal structure of a sample holder in the charged particle beam apparatus according to the third embodiment of the present invention.

As shown in FIG. 10, a charged particle beam apparatus 102 according to the present embodiment includes a sample holder 206 instead of the sample holder 6 of the first embodiment. Further, as shown in FIG. 10, the charged particle beam apparatus 102 includes the sample holder 206 instead of the sample holder 6 of the first embodiment.

Hereinafter, the description will be given centering on differences from the first embodiment.

As shown schematically in FIG. 10, the sample holder 206 includes a tilting base 264A (first tilting base), a tilting base 264B (second tilting base), and a spur gear 270 (third gear, driving force supplier) instead of the tilting bases 64A and 64B and the worm 70 in the sample holder 6.

The tilting bases 264A and 264B have the same shape. The outer shape of the tilting base 264A (264B) is a substantially half-moon shape when viewed from the y-axis direction, and a plane portion 264a is formed at a position facing the arc portion. A sample holding portion 64c (not shown) is disposed on the plane portion 264a, similarly to the plane portion 64b of the tilting base 64A (64B) of the first embodiment.

The tilting bases 264A and 264B are accommodated in the hole portion 63a (not shown) side by side in the x-axis direction. Positions of the tilting bases 264A and 264B in the y-axis direction are positioned by a positioning unit (not shown) on the inner peripheral portion of the hole portion 63a.

The tilting base 264A (264B) includes a turning support portion 264b and a spur gear 264c.

The turning support portion 264b supports the tilting base 264A (264B) with respect to the turning base 63 (not shown) to be turnable about the axis S1 (S2) similar to that of the first embodiment. The configuration of each turning support portion 264b is not particularly limited as long as the tilting bases 264A and 264B can be supported to be turnable about the axis S1 and the axis S2, respectively.

For example, the turning support portion 264b may have the same configuration as the turning support portion 164b of the second embodiment.

For example, the turning support portion 264b may have a configuration in which the roller 65 and the guide groove 64e are combined as in the first embodiment.

The spur gear 264c of the tilting base 264A (264B) is formed such that the pitch circle center is coaxial with the axis S1 (S2) on an arc-shaped outer periphery of the tilting base 264A (264B). The spur gear 264c of the tilting base 264A constitutes a first gear having the axis S1 which the first turning axis as the pitch circle center. The spur gear 264c of the tilting base 264B constitutes a second gear having the axis S2 which the second turning axis as the pitch circle center.

The spur gear 270 includes a module which meshes with each spur gear 264c. The spur gear 270 is disposed at a position where the spur gear 270 meshes with each spur gear 264c at a middle portion below the tilting bases 264A and 264B.

A drive unit 266 is configured by deleting the gears 74 and 72 from the drive unit 66 of the first embodiment. Further, in the drive unit 266, at least the drive motor 73 is disposed at a position coaxial with the pitch circle center of the spur gear 270 in the turning base 63.

The drive motor 73 in the present embodiment is fixed to the spur gear 270 at a tip of the output shaft 73a. The drive motor 73 in the present embodiment rotates the spur gear 270 counterclockwise (see solid line arrow) or clockwise (see broken line arrow) shown in the figure based on a control signal from the sample holder control unit 40.

However, the output shaft 73a of the drive motor 73 is not directly connected to the spur gear 270, but may be connected to the spur gear 270 via a transmission mechanism including an appropriate gear train, speed reduction mechanism, or the like.

According to the sample holder 206, when the output shaft 73a of the drive motor 73 rotates counterclockwise shown in the figure (clockwise shown in the figure), each spur gear 264c turns in the direction of the arrow SR1 (SR2). Accordingly, each plane portion 264a of the tilting bases 264A and 264B is tilted in the x-axis direction together with the sample holding portion 64c (not shown).

Thus, the sample holder 206 in the present embodiment is different from the sample holder 6 in the first embodiment in the drive mechanism for tilting the tilting bases 264A and 264B. However, similarly to the first embodiment, the sample holder 206 can tilt the tilting bases 264A and 264B together with each other in the x-axis direction based on the control signal from the sample holder control unit 40.

Thus, according to the charged particle beam apparatus 102, the sample can be quickly disposed and replaced, similarly to the first embodiment. In addition, the charged particle beam apparatus can form a sample safely and efficiently even in a case of processing a plurality of samples.

Further, according to the present embodiment, since the driving force is transmitted to the tilting bases 264A and 264B by the meshing of the spur gears, the manufacturing cost of the tilting bases 264A and 264B is reduced compared with a case where the worm wheel is formed.

### Fourth Embodiment

A charged particle beam apparatus according to a fourth embodiment of the present invention will be described.

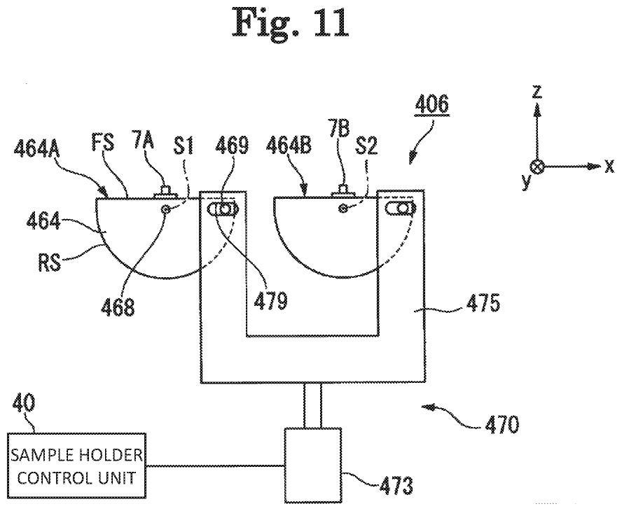

FIG. 11 is a schematic front view showing an example of an internal structure of a sample holder in the charged particle beam apparatus according to the fourth embodiment of the present invention. In FIG. 11, the z-axis direction is a direction orthogonal to the x-axis direction and the y-axis direction.

Among the configurations of the fourth embodiment, configurations other than those described below are the same as those in the first or second embodiment.

A sample holder 406 includes a first tilting base 464A, a second tilting base 464B, and a driving force supplier 470. The first tilting base 464A includes a tilting base body 464, a turning support portion 468, and an engaging portion 469.

The tilting base body 464 is formed in a substantially cylinder shape that is substantially a semicircular when viewed from the y-axis direction. The tilting base body 464 includes a plane portion FS and an arc portion RS on an outer periphery thereof. The sample 7A is disposed on the plane portion FS via a sample holding portion and a TEM grid.

The turning support portion 468 is formed in a cylindrical pin shape, for example. The turning support portion 468 protrudes in the y-axis direction from an end surface of the tilting base body 464 in the y-axis direction. A central axis of the turning support portion 468 coincides with the axis S1. The turning support portion 468 supports the tilting base body 464 such that the tilting base body 464 can turn about the axis S1.

The engaging portion 469 is formed in a cylindrical pin shape, for example. The engaging portion 469 protrudes in the y-axis direction from the end surface of the tilting base body 464 in the y-axis direction. The engaging portion 469 is separated from the turning support portion 468 and is disposed near the arc portion RS. A separation direction of the turning support portion 468 and the engaging portion 469 is parallel to the plane portion FS.

The configuration of the second tilting base 464B is the same as that of the first tilting base 464A. The turning support portion 468 of the second tilting base 464B supports the tilting base body 464 such that the tilting base body 464 can turn about the axis S2. The sample 7B is disposed on the plane portion FS via a sample holding portion and a TEM grid.

The driving force supplier 470 includes a drive arm 475 and a drive source 473.

The drive arm 475 is formed in a substantially U-shaped plate shape when viewed from the y-axis direction. The drive arm 475 is disposed in the y-axis direction of the tilting bases 464A and 464B. The drive arm 475 is disposed with both tip portions directed in the z-axis direction. Engagement portions 479 are formed at both tip portions of the drive arm 475. The positions of the engagement portions 479 at both tip portions in the z-axis direction are the same. The engagement portion 479 is a through hole penetrating the drive arm 475 in the y-axis direction, for example. The engagement portion 479 is formed in an oval shape when viewed from the y-axis direction. In the oval of the engagement portion 479, the major axis direction is the x-axis direction, and the minor axis direction is the z-axis direction. The engagement portion 479 is inserted with an engaging portion 469 of each of the tilting bases 464A and 464B. At this time, the plane portions FS of the tilting bases 464A and 464B are disposed in the same plane or at the same tilting angle. Accordingly, the samples 7A and 7B disposed on the plane portions FS of the tilting bases 464A and 464B have the same angle about the y-axis.

A drive source 473 is connected to a base end portion of the drive arm 475. The drive source 473 moves the drive arm 475 in the z-axis direction based on a control signal from the sample holder control unit 40. The drive source 473 is, for example, a piezoelectric element. The drive source 473 may be a ball screw mechanism, for example.

Next, the operation of the sample holder 406 will be described.

The drive source 473 moves the drive arm 475 in the z-axis direction. The engagement portion 479 of the drive arm 475 moves the engaging portion 469 of each of the tilting bases 464A and 464B in the z-axis direction. Accordingly, each of the tilting bases 464A and 464B turns about the axis S1 and the axis S2. As the tilting bases 464A and 464B turns, the engaging portion 469 moves in the x-axis direction. Since the engagement portion 479 of the drive arm 475 is formed in an oval shape, the engaging portion 469 is allowed to move in the x-axis direction. The angle of the samples 7A and 7B disposed on the plane portion FS about the y-axis is changed by the turning of the tilting bases 464A and 464B. Accordingly, the processing and observation can be performed on the samples 7A and 7B from various angles. When the drive source 473 is driven in the same manner, the angles of the sample 7A and the sample 7B are changed similarly. Therefore, the sample 7A and the sample 7B can be processed similarly.

The charged particle beam apparatus including the sample holder 406 can quickly dispose and replace the sample, similarly to the first or second embodiment. In addition, the charged particle beam apparatus can form a sample safely and efficiently even in a case of processing a plurality of samples.

The sample holder 406 is attachable and detachable from the upper surface of the sample stage 10 shown in FIG. 2. That is, the drive source 473 supplies a driving force in the z-axis direction intersecting (orthogonal to) the upper surface of the sample stage 10. The sample holder 406 is compact in the x-axis direction and the y-axis direction. Therefore, even when there are structures on the sample stage 10 in the x-axis direction and the y-axis direction, the sample holder 406 which does not interfere with the structure can be provided.

In the fourth embodiment, the drive arm 475 is formed in a substantially U-shaped plate shape. In contrast, the drive arm 475 may be configured by a link mechanism. For example, the drive arm 475 may include a base arm connected to the drive source 473 and a pair of turning arms pin-coupled to both end portions of the base arm. A circular through hole is formed at a tip of the turning arm when viewed from the y-axis direction. The engaging portion 469 of each of the tilting bases 464A and 464B is inserted into the through hole. Accordingly, when the tilting bases 464A and 464B are turned by the drive source 473, the positional accuracy of the tilting bases 464A and 464B is improved.

### Modification of Fourth Embodiment

A charged particle beam apparatus according to a modification of the fourth embodiment will be described.

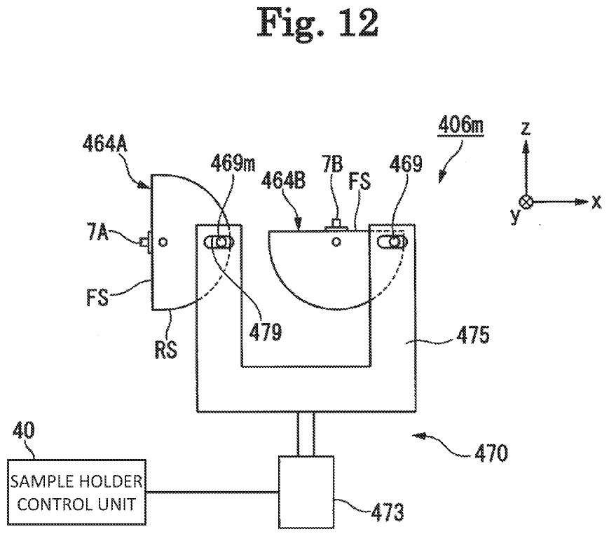

FIG. 12 is a schematic front view showing an example of an internal structure of a sample holder in the charged particle beam apparatus according to the fourth embodiment of the present invention.

In the modification with respect to the fourth embodiment, the position of an engaging portion 469m of the first tilting base 464A is different. Among the configurations of the modification, configurations other than those described below are the same as those in the fourth embodiment.

The engaging portion 469m of the first tilting base 464A is separated from the turning support portion 468 and is disposed near the arc portion RS. A separation direction of the turning support portion 468 and the engaging portion 469m is a direction intersecting (orthogonal to) the plane portion FS. The position of the engaging portion 469 of the second tilting base 464B is the same as in the fourth embodiment.

The engagement portion 479 of the drive arm 475 is inserted with the engaging portion 469m of each of the tilting bases 464A and 464B. Accordingly, the plane portion FS of the first tilting base 464A and the plane portion FS of the second tilting base 464B are disposed at different tilting angles an orthogonal state). At this time, the samples 7A and 7B disposed on the plane portions FS of the tilting bases 464A and 464B are greatly different in angle about the y-axis.

In a sample holder 406m of the modification, the sample 7A and the sample 7B can be processed from greatly different angles.

In the modification, one engaging portion 469m is formed near the arc portion RS. In contrast, a plurality of engaging portions 469m may be formed along the arc portion RS. In this case, when a different engaging portion 469m is inserted into the engagement portion 479, the tilting angle of the plane portion FS is changed. Accordingly, the angle of the sample 7A about the y-axis can be changed.

### Fifth Embodiment

A charged particle beam apparatus according to a fifth embodiment of the present invention will be described.

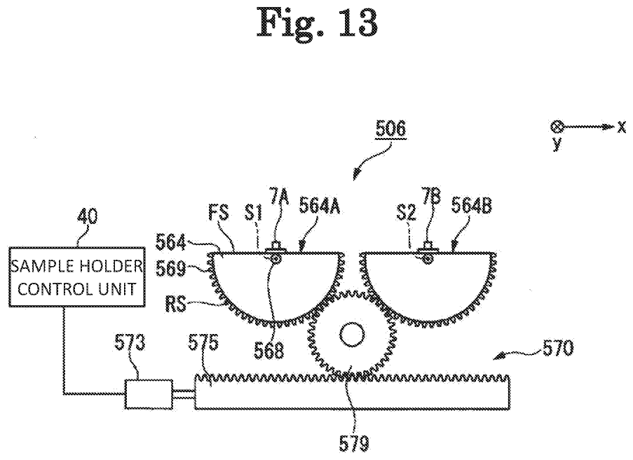

FIG. 13 is a schematic front view showing an example of an internal structure of a sample holder in the charged particle beam apparatus according to the fifth embodiment of the present invention.

Among the configurations of the fifth embodiment, configurations other than those described below are the same as those in the first or third embodiment.

A sample holder 506 includes a first tilting base 564A, a second tilting base 564B, and a driving force supplier 570. The first tilting base 564A includes a tilting base body 564, a turning support portion 568, and an arc gear (first gear) 569.

The tilting base body 564 is formed in a substantially cylinder shape that is substantially a semicircular when viewed from the y-axis direction. The tilting base body 564 includes a plane portion FS and an arc portion RS on an outer periphery thereof. The sample 7A is disposed on the plane portion FS via a sample holding portion and a TEM grid.

The turning support portion 568 is formed in a cylindrical pin shape, for example. The turning support portion 568 protrudes in the y-axis direction from an end surface of the tilting base body 564 in the y-axis direction. A central axis of the turning support portion 568 coincides with the axis The turning support portion 568 supports the tilting base body 564 such that the tilting base body 564 can turn about the axis S1.

The arc gear 569 is a part of the outer periphery of the gear. The arc gear 569 is formed on the arc portion RS of the tilting base body 564. The pitch circle center of the arc gear 569 coincides with the axis S1.

The configuration of the second tilting base 564B is the same as that of the first tilting base 564A. The turning support portion 568 of the second tilting base 564B supports the tilting base body 564 such that the tilting base body 564 can turn about the axis S2. The pitch circle center of the arc gear (second gear) 569 coincides with the axis S2. The sample 7B is disposed on the plane portion FS via a sample holding portion and a TEM grid.

The driving force supplier 570 includes a pinion gear (third gear) 579, a rack gear 575, and a drive source 573.

The pinion gear 579 is a spur gear. The pinion gear 579 is disposed at a middle portion between the tilting bases 564A and 564B in the x-axis direction. The pinion gear 579 meshes with the arc gears 569 of the tilting bases 564A and 564B. That is, one pinion gear 579 meshes with the arc gears 569 of the tilting bases 564A and 564B.

The rack gear 575 is disposed in parallel to the x-axis direction. The rack gear 575 is disposed on a side opposite to the tilting bases 564A and 564B with the pinion gear 579 interposed therebetween. The rack gear 575 meshes with the pinion gear 579. At this time, the plane portions FS of the tilting bases 564A and 564B are disposed in parallel or in the same plane. The samples 7A and 7B disposed on the plane portions FS of the tilting bases 564A and 564B have the same angle about the y-axis.

The drive source 573 is connected to the rack gear 575. The drive source 573 moves the rack gear 575 in the x-axis direction based on a control signal from the sample holder control unit 40. The drive source 573 is a ball screw mechanism, for example.

The operation of the sample holder 506 will be described.

The drive source 573 moves the rack gear 575 in the x-axis direction. The rack gear 575 rotates the pinion gear 579. The pinion gear 579 turns the tilting bases 564A and 564B in the same manner via the arc gear 569. The angle of the samples 7A and 7B disposed on the plane portion FS about the y-axis is changed by the turning of the tilting bases 564A and 564B. Accordingly, the processing and observation can be performed on the samples 7A and 7B from various angles. When the drive source 573 is driven in the same manner, the angles of the sample 7A and the sample 7B are changed similarly. Therefore, the sample 7A and the sample 7B can be processed similarly.

The charged particle beam apparatus including the sample holder 506 can quickly dispose and replace the sample, similarly to the first or third embodiment. In addition, the charged particle beam apparatus can form a sample safely and efficiently even in a case of processing a plurality of samples.

### Modification of Fifth Embodiment

A charged particle beam apparatus according to a modification of the fifth embodiment will be described.

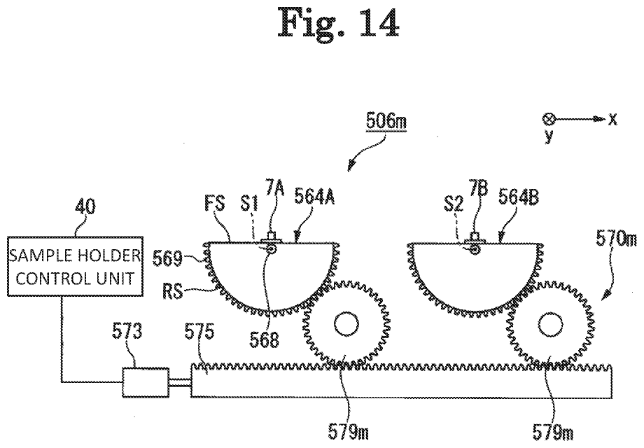

FIG. 14 is a schematic front view showing an example of an internal structure of a sample holder in the charged particle beam apparatus according to the fifth embodiment of the present invention.

In the modification with respect to the fifth embodiment, a separate pinion gear 579m meshes with the arc gear 569 of each of the tilting bases 564A and 564B. Among the configurations of the modification, configurations other than those described below are the same as those in the fifth embodiment.

The pinion gear 579m is disposed below the first tilting base 564A. The pinion gear 579m meshes with the arc gear 569 of the first tilting base 564A. The same applies to the second tilting base 564B. That is, respective pinion gears 579m mesh with the arc gears 569 of respective the tilting bases 564A and 564B. The pinion gears 579m have the same number of teeth.

The rack gear 575 meshes with each pinion gear 579m. At this time, the plane portions ES of the tilting bases 564A and 564B are disposed in parallel or in the same plane. The samples 7A and 7B disposed on the plane portions ES of the tilting bases 564A and 564B have the same angle about the y-axis.

The charged particle beam apparatus including a sample holder 506m according to the modification can quickly dispose and replace the sample, similarly to the first or third embodiment. In addition, the charged particle beam apparatus can form a sample safely and efficiently even in a case of processing a plurality of samples.

In the modification, the pinion gears 579m have the same number of teeth. In contrast, the number of teeth of the pinion gears 579m may be different. In this case, when the rack gear 575 is moved in the x-axis direction, the tilting bases 564A and 564B are turned at different angles. Accordingly, the plane portion FS of the first tilting base 564A and the plane portion FS of the second tilting base 564B are disposed at different tilting angles. At this time, the samples 7A and 7B disposed on the plane portions FS of the tilting bases 564A and 564B are different in angle about the y-axis. Therefore, the sample 7A and the sample 7B can be processed from different angles.

In the description of the above embodiments, an example is described in which the FIB lens barrel 1 is disposed in the vertical direction, and the EB lens barrel 2 and the GIB lens barrel 3 are disposed to be tilted with respect to the vertical axis. However, the positional relationship between the FIB lens barrel 1 and the EB lens barrel 2 or the FIB lens barrel 1 and the GIB lens barrel 3 may be interchanged.

In the description of the above embodiments, an example is described in which the charged particle beam which can be emitted by the charged particle beam apparatus is three types of FIB, EB, and GIB. However, the type of charged particle beam and the number of irradiations are not limited thereto. The type and number of charged particle beam are not particularly limited as long as there are one or more.

In the description of the above embodiments, an example is described in which the samples 7A and 7B are held on the TEM grid 67. However, the method for attaching the sample on the tilting base 64 is not limited to the TEM grid 67.

In the description of the above embodiments, an example is described in which the sample holder is provided with a tilting stage for tilting the first tilting base and the second tilting base which are tilted in the x-axis direction in the y-axis direction orthogonal the x-axis. However, depending on the application or the configuration of the sample stage 10, the sample holder may not be provided with a tilting stage tilting in the y-axis direction.

The first tilting base and the second tilting base in the sample holder may be movably supported by a moving stage other than the tilting stage. Examples of the moving stage other than the tilting stage include a rotation stage and a translation stage.

In the description of the above embodiments, an example is described in which the plane portions of the first tilting base and the second tilting base are tilted in parallel to each other. However, the first tilting base and the second tilting base may be tilted in opposite directions by being turned in opposite directions about the respective turning axes. For example, in the first embodiment, when a twist direction of the teeth of the worm wheel 64a of the tilting base 64A and a twist direction of the teeth of the worm wheel 64a of the tilting base 64B are opposite, the tilting directions of the tilting bases 64A and 64B are also opposite.

In the description of the above embodiments, an example is described in which the first tilting base and the second tilting base are disposed on a straight line extending in a direction orthogonal to the first turning axis and the second turning axis. However, the first tilting base and the second tilting base may be disposed at positions separated from each other in the y-axis direction.

In the description of the above embodiments, an example is described in which the first tilting base and the second tilting base are interlocked with each other so as to be tilted at the same tilting angle. However, the tilting angles may be different as long as the first tilting base and the second tilting base can be interlocked with each other. In this case, a tilting angle range, a tilting speed, or the like of the first tilting base and the second tilting base can be made different from each other.

In the first embodiment and the third embodiment, an example is described in which the first gear and the second gear are formed on the outer peripheral portions of the first tilting base and the second tilting base, respectively. However, when the first gear and the second gear are disposed coaxially with the first turning axis and the second turning axis, respectively, the first gear and the second gear may be disposed on lateral sides of the first tilting base and the second tilting base. In this case, pitch circle diameters of the first gear and the second gear may be set regardless of outer diameters of the first tilting base and the second tilting base.

Further, the first gear and the second gear may be connected to the body portions of the first tilting base and the second tilting base via a clutch or the like for releasing the transmission of the driving force. In this case, the rotation of one of the first tilting base and the second tilting base may be selectively stopped by a clutch or the like. For example, of the first tilting base and the second tilting base, the tilting base which is not processed or the like may be released from the transmission of the driving force during the processing or the like.

As in such a modification, the first tilting base and the second tilting base may be driven by a single drive source so as to be interlocked. That is, the first tilting base and the second tilting base may not always be tilted together with each other.

In the description of the above embodiments, an example is described in which the sample holder includes the first tilting base and the second tilting base. However, for the tilting base provided in the sample holder, there may be three or more tilting bases tilted by the same drive source.

In the above embodiments, when a broad beam having a large beam diameter covering the sample 7A and the sample 7B disposed on the first tilting base and the second tilting base is emitted from the GIB lens barrel 3, since two samples can be processed at the same incident angle at the same time, the sample can be formed efficiently.

Preferred embodiments of the present invention have been described above, but the present invention is not limited to these embodiments. Additions, omissions, substitutions, and other modifications can be made without departing from the scope of the present invention.

In addition, the present invention is not limited by the above description, and is limited only by the appended claims.

This application is based on Japanese Patent Application No. 2017-060903 filed with the Japan Patent Office on Mar. 27, 2017, and Japanese Patent Application No. 2018-055231 filed with the Japan Patent Office on Mar. 22, 2018, and the entire contents of Japanese Patent Application No. 2017-060903 and Japanese Patent Application No. 2018-055231 are incorporated herein by reference.

1. A charged particle beam apparatus, comprising:
a charged particle beam lens barrel that irradiates a sample with a charged particle beam;
a first tilting base that includes a first sample holding portion capable of holding the sample, and holds the first sample holding portion to be turnable about a first turning axis;
a second tilting base that includes a second sample holding portion capable of holding the sample, and holds the second sample holding portion to be turnable about a second turning axis parallel to the first turning axis; and
a driving force supplier configured to supply the first tilting base and the second tilting base with a driving force for turning the first tilting base in association with the second tilting base.

2. The charged particle beam apparatus according to claim 1, wherein the first tilting base and the second tilting base are disposed in a direction intersecting the first turning axis and the second turning axis.

3. The charged particle beam apparatus according to claim 1, further comprising:
a sample stage that includes a rotation stage being rotatable about a rotation axis extending in a direction orthogonal to the first turning axis and the second turning axis,
wherein the first tilting base and the second tilting base are provided on a detachable sample holder on an upper surface of the sample stage.

4. The charged particle beam apparatus according to claim 1, further comprising a tilting stage that turns the first tilting base and the second tilting base about a third turning axis orthogonal to the first turning axis and the second turning axis.

5. The charged particle beam apparatus according to claim 1,
wherein the first tilting base includes a first gear having the first turning axis as a pitch circle center,
the second tilting base includes a second gear having the second turning axis as a pitch circle center, and
the driving force supplier includes a third gear meshing with the first gear and the second gear.

6. The charged particle beam apparatus according to claim 5,
wherein the first gear is a first worm wheel;
the second gear is a second worm wheel; and
the third gear is a worm meshing with the first worm wheel and the second worm wheel.

7. The charged particle beam apparatus according to claim 1, wherein the driving force supplier includes a drive rod that transmits the driving force to the first tilting base and the second tilting base.

8. The charged particle beam apparatus according to claim 3, wherein the driving supplier supplies the driving force in a direction intersecting the upper surface of the sample stage.
